(19) United States
(12) Patent Application Publication
(10) Pub. No.: US 2022/0372653 A1
(43) Pub. Date: Nov. 24, 2022

(54) METHOD FOR REDUCING STRUCTURAL DAMAGE TO THE SURFACE OF MONOCRYSTALLINE ALUMINIUM-NITRIDE SUBSTRATES, AND MONOCRYSTALLINE ALUMINIUM-NITRIDE SUBSTRATES THAT CAN BE PRODUCED BY A METHOD OF THIS TYPE

(71) Applicant: FRAUNHOFER-GESELLSCHAFT ZUR FÖRDERUNG DER ANGEWANDTEN FORSCHUNG E.V., München (DE)

(72) Inventors: Boris EPELBAUM, Erlangen (DE); Stephan MÜLLER, Erlangen (DE); Elke MEISSNER, Erlangen (DE)

(73) Assignee: FRAUNHOFER-GESELLSCHAFT ZUR FÖRDERUNG DER ANGEWANDTEN FORSCHUNG E.V., München (DE)

(21) Appl. No.: 17/765,476

(22) PCT Filed: Sep. 30, 2020
(86) PCT No.: PCT/EP2020/077324

§ 371 Date: Mar. 31, 2022

(30) Foreign Application Priority Data
Oct. 1, 2019 (DE) 10 2019 215 122.1

(51) Int. Cl. C30B 33/02; C30B 29/40

(52) U.S. Cl. CPC C30B 33/02; C30B 29/403

(57) ABSTRACT

The present invention relates to a method for reducing structural damage to the surface of monocrystalline aluminium-nitride substrates, according to which the substrate undergoes thermal treatment in a crucible in an autoclave, during which treatment the aluminum-nitride substrate is sublimated in the damaged regions of the surface of the substrate and is removed. The method is used to prepare the surface of monocrystalline aluminium-nitride (AlN), in particular the aim of the invention is to eliminate, or at least significantly reduce near-surface structural damage to the monocrystalline material caused by mechanical processing. The invention also relates to aluminium-nitride substrates that are treated in this way.

The present invention relates to a method for reducing structural damage to the surface of monocrystalline aluminium-nitride substrates, in which the substrate undergoes heat treatment in a crucible in an autoclave, during which treatment the aluminium nitride is sublimated in the damaged regions of the surface of the substrate and is removed. The method is used to prepare the surface of monocrystalline aluminium nitride (AlN), in particular, the method is intended to eliminate, or at least significantly reduce, near-surface structural damage to the monocrystalline material caused by mechanical processing. The invention also relates to aluminium-nitride substrates that are treated in this way.

The production of substrate slices, e.g. wafers, or seed plates of grown monocrystals routinely involves several, usually mechanical, processing steps. These include circular grinding or surface grinding, sawing, edge rounding, lapping and polishing. If this mechanical processing finishes with a polishing step, near-surface damage to the monocrystalline material can often be identified.

Here, various near-surface regions are distinguished which may have defects. These first of all include, directly on the surface, the polished layer having a thickness of from 0.1 to 1 μm, followed by an underlayer that is in the range of from 1 to 100 μm from the surface, a deformation layer that is in the range of from 1 to 200 μm from the surface, and then the substrate, which is free of any effects.

In the prior art, surface treatments for removing such surface damage are known which may also relate to regions below the visible surface (“subsurface damage”). This includes chemical etching (Müller S., Sumakeris J., Brady M., Glass R., Hobgood H., Jenny J., Carter C. (2004). Defects in SiC substrates and epitaxial layers affecting semiconductor device performance. The European Physical Journal Applied Physics, 27(1-3), 29-35. doi:10.1051/epjap:2004085) and/or what is known as “chemical-mechanical polishing” (CMP) (Kevin Moeggenborg, Methods for polishing aluminum nitride, Patent Pub. No.: US 2010/0062601 A1, Pub. Date: Mar. 11, 2010). In particular, damage to a wafer edge after routine edge rounding may, however, in particular not be dealt with by a routine CMP step.

For monocrystals that are produced like the aluminium nitride (AlN) and silicon carbide (SiC) semiconductors by means of a PVT method, it has been found that the quality of the surface preparation of a seed surface can have a direct impact on the dislocation density of a material deposited thereon during growth. Removal or reduction of the near-surface damage results in a direct improvement in the dislocation density at the phase boundary between the seed and the newly grown crystal material and thus also reduces the dislocation density in the volume of the new monocrystal.

Existing near-surface damage, in particular on the wafer rim or the wafer edge, is often consciously accepted when using these wafers as seed plates for a growth process (e.g. volume crystal growth, but also in epitaxial processes such as MOVPE for layer deposition), meaning that new material of a lower crystalline quality is deposited in this edge region during a growth process. Therefore, attempts are made to shield these edge regions geometrically from the growth flow using other materials, and where necessary to additionally adapt the thermal boundary conditions in this region in a suitable way in order to prevent or at least reduce any material deposition at this point.

Both methods have significant drawbacks for the growth process. In the event of permitted deposition of material of lower crystalline quality, the crystal diameter that can be achieved with material of good crystalline quality is limited by this boundary condition. It may even result in a further decrease in the diameter of the region of good crystalline quality due to the material of lower crystalline quality parasitically growing into this region. The use of a geometric covering of a rim region that has surface damage results in similar drawbacks with regard to the reduction in diameter of the region of good crystalline quality. In particular, care must be taken to ensure that the polycrystalline deposition of material on the covering itself can be prevented, optionally by a suitable combination of the selection of the covering material and suitable thermal boundary conditions during the growth. Depending on the grown material and the required growth conditions, this often cannot be achieved, or can only be achieved with a great deal of effort.

In addition, the attempt to remove near-surface damage by means of chemical etching, e.g. by means of KOH solutions or melts, may be associated with other specific problems. These include surface contamination by the chemicals used that may potentially be difficult to remove and the development of a surface morphology that is disadvantageous for further use in growth processes. This is often attributed to the selective etching action on dislocations or other lattice defects.

Specifically for the optimisation of the nucleation during PVT growth of SiC semiconductors, it has been proposed to remove surface damage or surface contamination of the polished seed at the start of the growth process by reversing the temperature gradient (T(seed)>T(source)) as an in-situ step, in order to simultaneously prevent material deposition at low temperatures during the heating process (M. M. Anikin et al., Proc. ICSCRM-95, Kyoto, Japan, 1996, page 33 and Temperature gradient controlled Sic crystal growth, M. Anikin, R. Madar, Materials Science and Engineering B46 (1997) 278-286). This method is, however, difficult to implement in practice for SiC growth and is also not a replacement for mechanical polishing steps after a sawing process for SiC, since graphitisation of the surface can easily occur due to the non-stoichiometric sublimation of SiC and necessary, significant material removal, and therefore the surface of SiC is rendered unusable as a seed surface.

The problem addressed by the present invention was therefore to provide a method for treating surfaces of monocrystalline aluminium-nitride substrates with the aim of allowing there to be the most damage-free surface possible or as little damage as possible in near-surface regions of the aluminium-nitride substrate, with the most complete possible treatment being sought in all surface regions.

This problem is solved by the method for preparing the surface of monocrystalline aluminium nitride having the features of claim 1 and by corresponding monocrystalline aluminium-nitride substrates having the features of claim 12. The remaining dependent claims set out advantageous developments.

According to the invention, a method for preparing the surface of monocrystalline aluminium-nitride substrates is provided in which the substrate undergoes heat treatment in a crucible in an autoclave, which treatment results in the sublimation and removal of the aluminium nitride in the damaged regions on the surface. The heat treatment is carried out at temperatures of at least 2000° C. and in an atmosphere at an oxygen partial pressure of at most 10⁻⁴ mbar.

Because, unlike silicon carbide, the sublimation of aluminium nitride takes place substantially stoichiometrically, the thermal treatment of the aluminium-nitride semiconductor according to the invention can be carried out without the drawbacks described for silicon carbide. In particular, this means that, even with a longer treatment time or greater material removal, an undesired surface layer does not form due to a non-stoichiometric dislocation reaction.

The temperature of the heat treatment is selected such that sufficiently high aluminium partial pressure is generated at the substrate boundary surface to allow for material removal of the damaged material from the substrate surface by means of sublimation.

A sufficiently high and simultaneously controlled removal rate can be set by the absolute temperature in the autoclave, the temperature gradient on the substrate surface and the ambient pressure in the autoclave.

In order to prevent undesired oxidation of the surface of the aluminium-nitride substrate, the oxygen concentration within the autoclave is kept as low as possible. In this respect, a maximum oxygen partial pressure of 10⁻⁴ mbar is intended to be selected.

It is preferred for the heat treatment to be carried out at a temperature of from 2000 to 2350° C., preferably at 2150 to 2250° C.

Another preferred embodiment provides that the heat treatment is carried out under vacuum at a pressure of 1 mbar to 10⁻⁴ mbar or in a protective gas atmosphere at 1 mbar to 1.5×10³ mbar. Nitrogen, argon, helium or combinations thereof are preferably selected as the protective gas here.

It is also preferred that, during the heat treatment, the temperature gradient is at least 5° C./cm perpendicularly to the substrate surface.

Another preferred embodiment provides that, during the heat treatment, the temperature gradient is at most 1° C./cm in parallel with the substrate surface. When this gradient is observed, laterally homogeneous material removal is obtained.

In another preferred embodiment, during the heat treatment, the temperature gradient is in the range of at least 1° C./cm in parallel with the substrate surface. As a result, laterally inhomogeneous material removal can be achieved for producing tilting of the surface normal relative to the <0001> crystal axis.

It is preferred for the nitrogen-polar surface of aluminium nitride to be removed from the substrate in a specific manner at an orientation of +/−5° relative to the <0001> crystal axis.

It is more preferred for carbon in the form of carbon-containing species to be comprised in the atmosphere in this autoclave during the heat treatment. By means of these species, aluminium droplets can be prevented from forming on the treated aluminium-nitride surface during cooling. This is preferably implemented in that part of the inner surface of the crucible, in which the aluminium-nitride substrate is located, contains or consists of tantalum carbide, such that a carbon partial pressure develops during the heat treatment.

The method according to the invention is particularly suitable for removing damage caused by a pretreatment of the substrate, in particular by a sawing process, a grinding process, a polishing process or combinations of these processes, and therefore for making it possible to provide surfaces that are substantially free of damage.

It is more advantageous that damage below the surface of the substrate can also be removed using the method according to the invention. It is likewise possible for damage in the rim region and/or to the edges of the substrate to be removed.

According to the invention, a monocrystalline aluminium-nitride substrate is also provided which is substantially free of damage on the surface or in near-surface regions.

The subject matter according to the invention will be explained in greater detail with reference to the following figures and examples, without restricting it to the specific embodiments set out here.

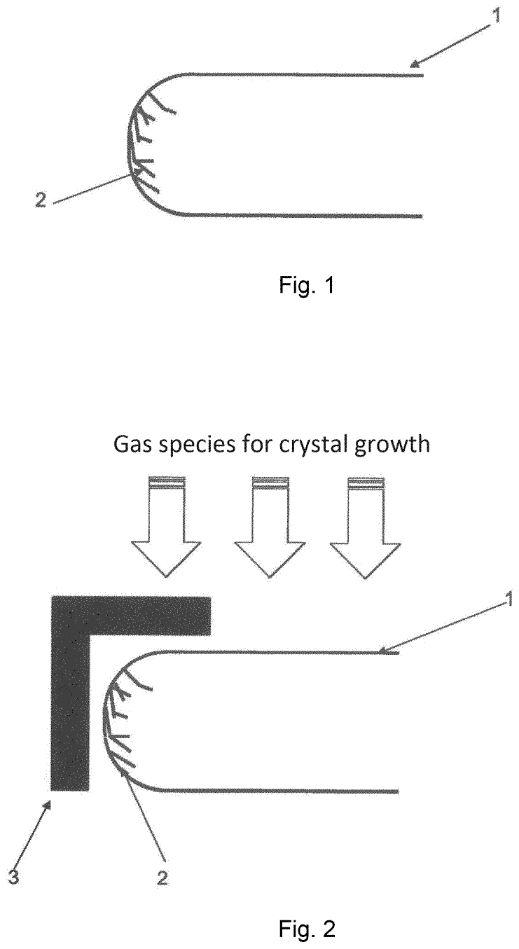

FIG. 1 is a schematic view of what happens with a rounded-edge wafer.

FIG. 2 shows a wafer in the growth process with a shielded wafer edge.

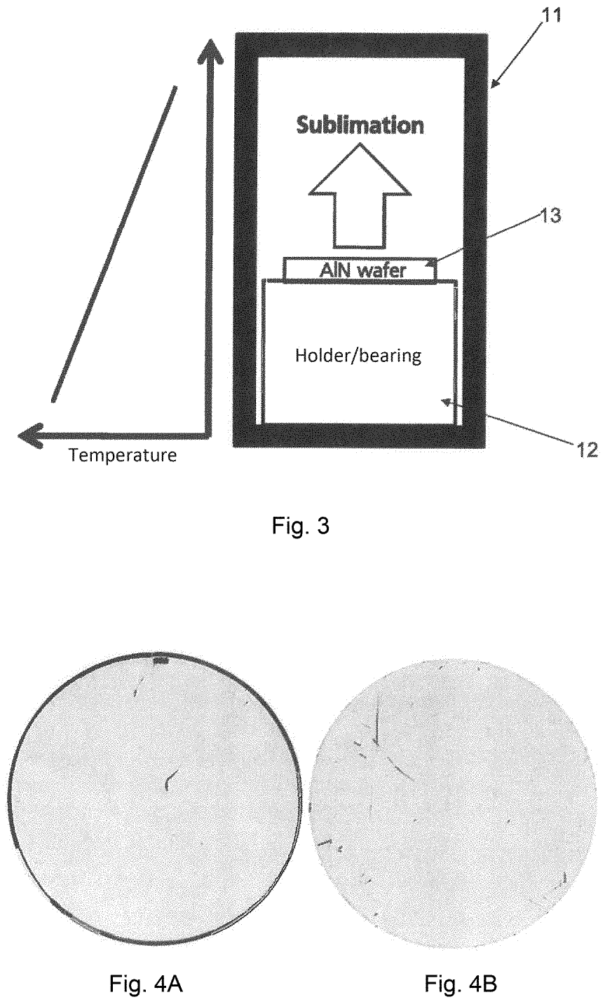

FIG. 3 shows the structure of a crucible used according to the invention.

FIG. 4 shows X-ray topography images of mechanically polished and CMP-polished AlN wafers once without thermal treatment (a) and once with thermal treatment (b).

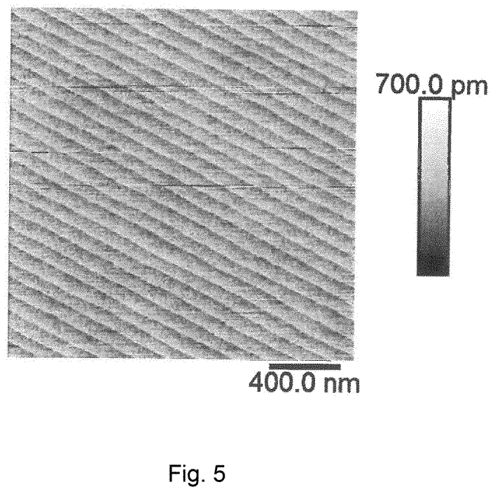

FIG. 5 shows an AFM image of an AlN wafer processed according to the invention.

FIG. 1 shows a wafer 1 that has undergone mechanical edge rounding. In this mechanical processing, structural damage 2 to the rounded wafer edge occurs. According to the prior art, wafers that have been previously damaged in this way generally undergo a growth process, with an attempt being made to shield the edge regions by means of covers 3. This is shown in FIG. 2.

FIG. 3 shows a crucible 11 used according to the invention, in which the aluminium-nitrite wafer is arranged on a holder 12. In this case, partial sublimation occurs on the surface of the aluminium-nitrite wafer 13 by means of a suitable temperature profile.

FIG. 4 shows X-ray topography images of a wafer mechanically processed according to the prior art (FIG. 4a) and a wafer processed according to the invention (FIG. 4b). It can be seen here that, in FIG. 4a, the wafer has a dark contrast on the wafer rim. This is the damage to the rim region resulting from the mechanical processing. The view in FIG. 4b then shows a wafer thermally treated according to the invention, which does not have any mechanical damage at all on the wafer rim, with no dark contrast being visible here.

FIG. 5 shows an AFM image of an AlN wafer according to the invention, with the surface having a stepped structure here. This wafer surface can then be used directly as a seed plate for a new PVT growth process for producing aluminium-nitrite crystals.

### EXAMPLE

The wafer is placed onto a TaC ceramic plate on the crucible base with the surface to be treated upwards within the tungsten crucible (typical height: 3 cm). Here, the diameter of the crucible is determined by the size of the wafer diameter and typically exceeds this by >1 cm. At the rim of the TaC ceramic described, additional AlN polymaterial (mass of the size of the mass of the wafer to be treated) having the fewest possible impurities of oxygen (<200 ppm) is added in order to produce an additional partial pressure on AlN species in the gas phase during the thermal treatment of the wafer surface to better control the removal of AlN material from the wafer surface by sublimation. For the process control, as is common, the temperature at the crucible lid (control temperature) is pyrometrically determined and is set for the various process steps in a targeted manner. Care should be taken here to ensure that, for the described crucible configuration, the control temperature is 50-70° C. below the temperature of the wafer surface to be treated.

For this configuration, it is then inserted into an autoclave and exposed to the following process conditions (the stated temperature corresponds to the control temperature here):
1. Before the heating step and during a first heating step up to approx. 500-700° C., oxygen residues in the autoclave should be reduced as far as possible by flushing multiple times with >5N nitrogen (720 mbar) and repeated evacuation to a vacuum of <1E-2 mbar. As a last step, the autoclave is filled with >5N nitrogen (720 mbar).
2. By heating (RF heating or resistance heating), the control temperature is increased to 2100° C. at a rate of 12-15° C./min.
3. By heating, the control temperature is increased from 2100° C. to 2200° C. at a rate of 2.5-3.0° C./min.
4. The temperature of 2200° C. is maintained for 5-25 min in order to achieve typical surface removal of 20-50 μm. To do this, an axial temperature gradient of approx. 20° C./cm is aimed for on the wafer surface in the direction of the crucible lid. This gradient is set by the crucible geometry and a suitable selection of the geometry and material for the thermal insulation material surrounding the crucible within the autoclave.
5. The control temperature is then reduced by reducing the heating until room temperature is reached. Typical cooling rates are 4-5° C./min.

1-12. (canceled)

13. A method for preparing the surface of a monocrystalline aluminium-nitride substrate, the method comprising heating the substrate undergoes in a crucible in an autoclave, which treatment results in a sublimation and removal of the aluminium nitride in damaged regions on the surface, wherein the heat treatment is carried out at a temperature of at least 2000° C. and in an atmosphere at an oxygen partial pressure of at most 10⁻⁴ mbar.

14. The method according to claim 13, wherein the heat treatment is carried out at a temperature of from 2000 to 2350° C.

15. The method according to claim 13, wherein the heat treatment is carried out under vacuum at 1 mbar to 10⁻⁴ mbar or in a protective gas atmosphere at 1 mbar to 1.5×10³ mbar, wherein nitrogen, argon, helium or a combination thereof is selected as the protective gas.

16. The method according to claim 13, wherein, during the heat treatment, the temperature gradient is at least 5° C./cm and the temperature gradient is perpendicular to the substrate surface.

17. The method according to claim 13, wherein, during the heat treatment, the temperature gradient is at most 1° C./cm and the temperature gradient is parallel to the substrate surface in order to allow for lateral homogeneous material removal.

18. The method according to claim 13, wherein, during the heat treatment, the temperature gradient is at least 1° C./cm and is parallel to the substrate surface, in order to set laterally inhomogeneous material removal for producing tilting of the surface normal relative to the <0001> crystal axis.

19. The method according to claim 13, wherein a nitrogen-polar surface of aluminium nitride is removed from the substrate in a specific manner at an orientation of +/−5° relative to the <0001> crystal axis.

20. The method according to claim 13, wherein the atmosphere comprises carbon.

21. The method according to claim 13, wherein the crucible comprises tantalum carbide, from which carbon is released during the heat treatment.

22. The method according to claim 13, wherein damage caused by pretreatment of the substrate is removed by a sawing process, a grinding process, a polishing process, or a combination thereof.

23. The method according to claim 13, which includes removing the damage below the surface of the substrate.

24. The method according to claim 13, which includes removing the damage in the rim region and/or to the edges of the substrate.

25. A method of producing monocrystalline aluminium-nitride substrate, the method comprising heating an aluminium-nitride substrate in a crucible in an autoclave, which treatment results in a sublimation and removal of the aluminium nitride in damaged regions on the surface, wherein the heat treatment is carried out at a temperature of at least 2000° C. and in an atmosphere at an oxygen partial pressure of at most 10⁻⁴ mbar.
